(19) United States
(12) Patent Application Publication
(10) Pub. No.: US 2003/0006842 A1
(43) Pub. Date: Jan. 9, 2003

(54) Split cascode driver

(76) Inventors: Andy Turudic, Hillsboro, OR (US); William H. Davenport, Portland, OR (US)

Correspondence Address: SKJERVEN MORRILL LLP, 25 METRO DRIVE, SUITE 700, SAN JOSE, CA, 95110, US

(21) Appl. No.: 09/898,602

(22) Filed: Jul. 3, 2001

(51) Int. Cl. H03F 3/45; H03F 1/22

(52) U.S. Cl. 330/253; 330/311

(57) ABSTRACT

Two transistors are coupled in a cascode topology between a load resistor and a first current source. A third transistor is coupled between the cascode transistor output terminal and a second current source. The current provided by the second current source causes a constant voltage drop across the load resistor and consequently a steady offset voltage at the cascode transistor output terminal. When the control transistor in the cascode circuit switches on, the current provided by the first current source provides an additional voltage drop at the cascode transistor output terminal.

### BACKGROUND

1. Field of Invention

Embodiments are related to cascode amplifier topologies that drive loads requiring mixed signal sources, and in particular to cascode amplifier topologies that provide both a steady state DC offset voltage/current and a modulating voltage/current at an output terminal.

2. Related Art

The cascode amplifier topology is well known and is commonly used to isolate the undesirable voltage variations caused by, for example, Miller capacitance in common source/emitter/cathode amplifiers. A “telescopic” cascode adds, for example, a common gate (FET), common base (BJT), or common control grid (vacuum tube) amplifier to the common source/emitter/cathode amplifier, respectively. Due to their desirable low noise characteristics, such cascode amplifiers are used to drive various electronic circuits and devices, such as electro-absorptive optical modulators (EAMs) and Mach-Zehnder optical modulators.

These electro-optical modulators are common in optical communications systems that use an electronic signal to modulate a light beam. EAMs include a bulk or epitaxial semiconducting material (e.g., Indium Phosphide (InP), Gallium Arsenide (GaAs)) that, in response to two discrete voltage levels across the material, changes between being opaque and transparent to selected laser frequencies. Mach-Zehnder modulators change light propagation speed through a crystal in response to voltage levels across the crystal, and thereby provide a shutter function from constructive and destructive interference due to the resulting phase shift. For proper operation, however, such electro-optical modulators typically require voltage levels that are different from the positive supply voltage or “top rail” voltage used to operate a typical cascode amplifier. Thus, in addition to the modulating voltage that is used to control the shutter function of the modulator, the cascode amplifier that drives the modulator must provide a steady state voltage level that is offset from the amplifier's “top rail” voltage. In a similar application, a directly modulated laser (DML) requires both a constant DC current and a modulating current for operation.

FIG. 1 illustrates a differential amplifier topology that may be used to drive, for example, an EAM that acts as a shutter for a laser. Transistors 102,104,106,108 are shown coupled in a cascode topology. The drain of transistor 102 and the source of transistor 104 are coupled at node 110. Similarly, the drain of transistor 106 is coupled to the drain of transistor 108 at node 112. The sources of transistors 102 and 106 are coupled at node 114. The gates of transistors 102,106 are coupled to input terminals 116,118, respectively. The gates of transistors 104,108 are coupled together at node 120 and receive cascode gate voltage level V_{CG} (e.g., −3.5 volts).

One terminal of load resistor 122 (e.g., 50 Ohm) is coupled at output terminal 124 to the drain of transistor 104. Similarly, one terminal of load resistor 126 (e.g., 50 Ohm) is coupled at output terminal 128 to the drain of transistor 108. The opposite terminals of resistors 122,126 are coupled together at node 130 and receive “top rail” supply voltage level V_{DD} (e.g., 0.0 volts).

Steady state (i.e., direct current (DC)) current source 132 (e.g., enhancement mode GaAs metal semiconductor FET (MESFET) providing 130 milliamperes (mA)) is coupled between node 114 and circuit supply voltage line 134, which receives voltage level V_{EE} (e.g., −7.5 volts). In some cases current source 132 is fixed (e.g., constant gate voltage) and in other cases current source 132 is variable (e.g., variable gate voltage), as illustrated by the intersecting dashed arrow in FIG. 1. This fixed/variable convention applies to all current sources shown in the drawings. The current sources shown in the drawings may also include conventional degeneration resistor (not shown) that is coupled to line 134. Current source 136 (e.g., providing 40 mA) is coupled between node 110 and line 134. Similarly, current source 138 (e.g., providing 40 mA) is coupled between node 112 and line 134.

During operation of the circuit shown in FIG. 1, with current flow through transistor 106 blocked by the voltage at terminal 118 (i.e., transistor 106 is off), current I₁, that is sourced by current source 138 passes through resistor 126 and transistor 108. Current I₁, causes a voltage drop across resistor 126 and a resulting steady state output voltage at output terminal 128 that is offset from the “top rail” voltage V_{DD}. When the gate voltage at terminal 118 is changed to allow current to flow through transistor 106, current I₂ that is sourced by current source 132 passes through resistor 126 and transistors 106,108. The combined currents I₁, and I₂ through resistor 126 cause a larger voltage drop across resistor 126 than the drop caused by current I₁, alone. Consequently, a voltage different from the steady state offset voltage exists at output terminal 128. In this way, by turning transistor 106 off and on the output voltage at terminal 128 is varied between two voltages at or below the “top rail” voltage level.

In many applications (e.g., optical beam modulation in high speed communication systems) the speed at which the output voltage at terminal 128 can switch between, and subsequently stabilize at, two discrete output voltage levels is important. For the circuit shown in FIG. 1, the transistor 108 channel is widened (e.g., 700 micrometers (μm)) to accommodate combined currents I₁ and I₂ and to maintain a desirable transistor 108 slew rate. It was discovered, however, that the increased device size and current causes additional excessive overshoot and undershoot of the required voltage levels during switching as the voltages settle to the desired values at the output terminal. What is required, therefore, is a cascode circuit topology that simultaneously provides a predetermined steady state output voltage level with a radio frequency AC output voltage modulation, and that provides reduced undershoot and overshoot.

### SUMMARY

A first current source, a first transistor, a second transistor, and a load resistor, in this order, are coupled in series. The transistors are coupled in a cascode topology with an output terminal between the second transistor and the resistor. A varying signal on the first transistor's control terminal causes a corresponding variable current in the resistor. Consequently, the voltage varies at the output terminal as the voltage drop across the resistor varies. In addition, a second current source and a third transistor, in this order, are coupled to the output terminal (i.e., to the node between the load resistor and the second transistor). The second current source causes a steady current to flow through the load resistor. This steady current results in a constant voltage drop across the resistor. Consequently, a steady state voltage exists at the output terminal that is offset from the “top rail” voltage. Thus two switchable output voltage levels are provided at the output terminal. A first offset voltage level is provided when only current from the second current source is passing through the resistor. When the combined currents from the first and second current sources are passing through the resistor, a second voltage level is provided. This circuit topology significantly reduces the amount of voltage overshoot and undershoot as the voltage levels at the output terminal settle at their desired values during switching. In another embodiment, this circuit topology is used to form a differential amplifier topology.

### BRIEF DESCRIPTION OF THE DRAWINGS

FIG. 1 is a schematic diagram of a cascode amplifier.

FIG. 2 is a schematic diagram of a second cascode amplifier.

FIG. 3 is a schematic diagram of a third cascode amplifier.

FIG. 4 is a diagrammatic view of an application of a cascode amplifier circuit.

FIG. 5 is a diagrammatic view of another application of a cascode amplifier circuit.

### DETAILED DESCRIPTION

Skilled artisans will understand that an electronic gain device typically includes at least two current handling terminals, and that the current passing between these two current terminals is controlled by a signal (e.g., voltage or current) present at a control terminal of the device. The embodiments described herein are in terms of field effect transistors (e.g., N-channel Gallium Arsenide (GaAs) metal semiconductor FETs (MESFETs)), hence the source/drain is illustrative of a current handling terminal and the electrically conductive gate is illustrative of a control terminal. GaAs provides a high speed semiconductor gain device allowing high voltage swings to be provided to the driven load. Other embodiments are constructed using various gain devices that include materials Indium Phosphide (providing high switching speed), Silicon Carbide (providing high voltage handling capacities (e.g., 12-20 volts across the circuit power supply)), Silicon-Germanium (providing high carrier mobility, more symmetrical electron-hole mobility, and narrow bandgap), and complementary metal oxide semiconductor (CMOS) (providing low power consumption). Other embodiments are constructed using various other electronic gain devices (e.g., metal oxide FETs, bipolar junction transistors, silicon controlled rectifiers, heterojunction bipolar transistors, vacuum tubes) in circuit topologies similar to the described topologies. The same reference number in several of the accompanying drawings refers to the same or similar element. Well known elements have been omitted from the drawings so as to more clearly illustrate various embodiments.

FIG. 2 is a diagram illustrating an embodiment of a amplifier circuit topology 200 that is used to drive, for example, a conventional shutter (light valve) for a laser (e.g., EAM, Mach-Zehnder) or a conventional direct modulated laser (DML). In one case circuit 200 is formed on a single integrated circuit die. As shown in FIG. 2, transistors 102,106,202,204 are coupled in a cascode topology. The transistor 102 drain and the transistor 202 source are coupled at node 110. Similarly, the transistor 106 drain and the transistor 204 source are connected at node 112. The sources of transistors 102 and 106 are coupled together at node 114. Current source 132 (e.g., MESFET providing approximately 130 mA, conventional mixer) is coupled between node 114 and voltage line 134, which receives supply voltage V_{EE} (e.g., −7.5 volts).

One terminal of load resistor 122 is coupled to the transistor 202 drain at output terminal 124. Similarly, one terminal of load resistor 126 is coupled to the transistor 204 drain at output terminal 128. The opposite terminals of resistors 122,126 are coupled to node 130, which receives “top rail” supply voltage level V_{DD} (e.g., 0.0 volts). The single resistors 122,126 are illustrative of various load resistances that may be used to provide the required voltage drops.

The transistor 206 drain is coupled to output terminal 124. Likewise, the transistor 208 drain is coupled to output terminal 128. Current sources 136,138 (e.g., MESFETs providing approximately 40 mA) are coupled between the transistor 206,208 sources, respectively, and voltage line 134. The gates of transistors 202,204,206,208 are coupled together and receive cascode gate voltage V_{CG} (e.g., −3.5 volts). In other cases, the gates of transistors 202,204,206,208 are coupled in other combinations, such as 202,204 and 206,208, or are not coupled.

During an illustrative operation of circuit 200, if transistor 106 is off, current I₁, sourced by current source 138, flows through resistor 126 and transistor 208. Current I₁, causes a voltage drop across resistor 126, thereby producing the steady state DC voltage level at output terminal 128 that is offset (e.g., in the range from 0 to −1 volt) from “top rail” supply voltage level V_{DD} at node 130. This DC offset output voltage level is varied by changing the value of I₁. In one case the offset output voltage level is set to provide a steady state driver voltage for an optical modulator device. In cases in which circuit 200 drives such a modulator, for example, the user adjusts I₁ to provide the specific offset voltage required for proper operation of the unique driven modulator, or the specific threshold current for a conventional direct modulated laser.

If transistor 106 is switched on (e.g., by a binary digital radio frequency signal received at input terminal 118), then current I₂, sourced by current source 132, flows through resistor 126 and transistors 106,204. The combined currents I₁ and I₂ (e.g., approximately 160 mA) through resistor 126 cause a larger voltage drop (e.g., 1-3 volts as required by a typical EAM) than the drop caused by I₁ alone, and consequently a voltage different from the steady state offset voltage exists at output terminal 128. The transistor 106,204,208 cascode topology is therefore “split” into one current path that provides a steady-state DC offset voltage, illustrated by the current path through transistor 208, and a second current path that provides variable AC voltage, illustrated by the current path through transistors 106 and 204. In other cases these split current paths provide any combination of steady state or varying signals to at least one of the output terminals. The modulating signal at the output terminal is are provided by introducing a varying signal (e.g., binary digital signal, multilevel digital signal, analog signal) at one or both of input terminals 116,118, or in some cases by varying current source 132.

The right side of circuit 200 is described above, and the left side of circuit 200 as defined by transistors 102, 202, 206 and resistor 122 operates in a similar manner. In one instance, complementary binary digital signals are provided to the differential amplifier input terminals 116,118.

The differential amplifier topology and balanced load resistors 122,126 of circuit 200 allow for fast switching of output voltage levels at output nodes 120,128. Circuit 200 is capable of driving two loads——one each at output nodes 124,128, respectively——although circuit 200 may only drive a single load. In cases in which a driven load is coupled to only one of the output terminals 124,128, a load resistor of approximately equal value (e.g., 50 Ohm) to the driven load is coupled to the other output terminal.

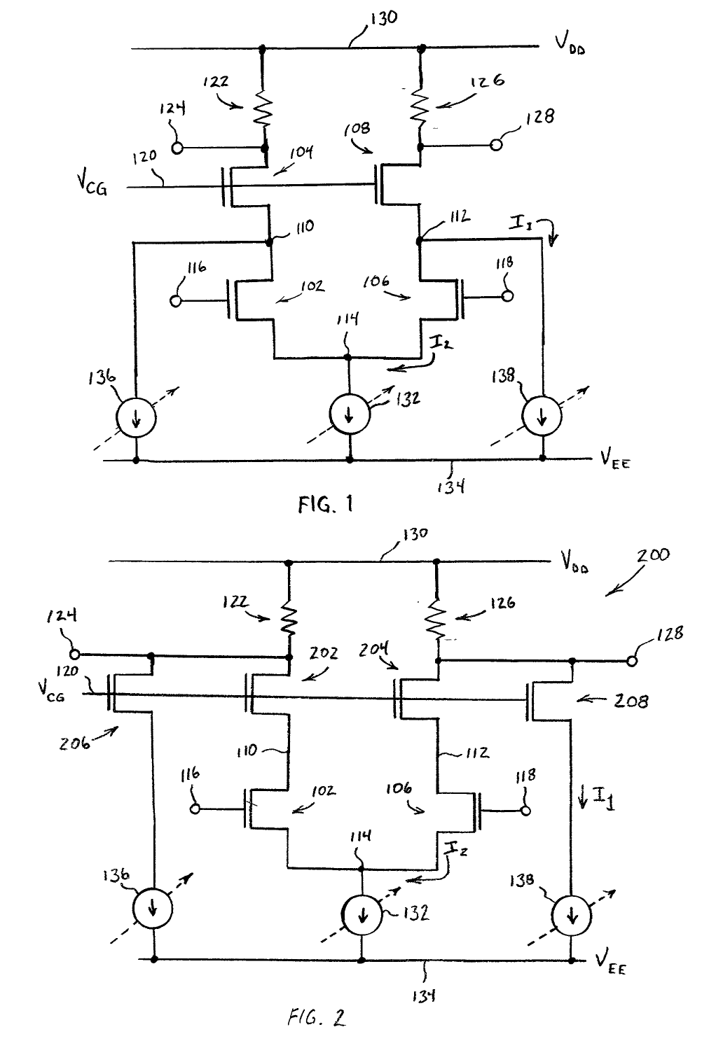

The “split cascode” circuit 200 topology allows the channel width of transistors 202,204 to be less than the channel width of transistors 104,108 (FIG. 1) for similar values of I₁ and I₂, thereby reducing undesired noise in transistors 202,204 (i.e., quieting the cascode gain devices). In one case the channel width for transistors 202,204 is reduced to approximately 600 μm from the 700 μm channel width required for transistors 104,108 (channel length for transistors 202,204 is 0.3 μm in one case). Based on conventional simulation (e.g., using SPICE) and experimental verification, the reduced channel width and reduced current handled by transistors 202,204 decreases the undesirable overshoot and undershoot from approximately ten percent for the circuit illustrated in FIG. 1 to approximately seven percent for circuit 200——an approximately 30 percent improvement.

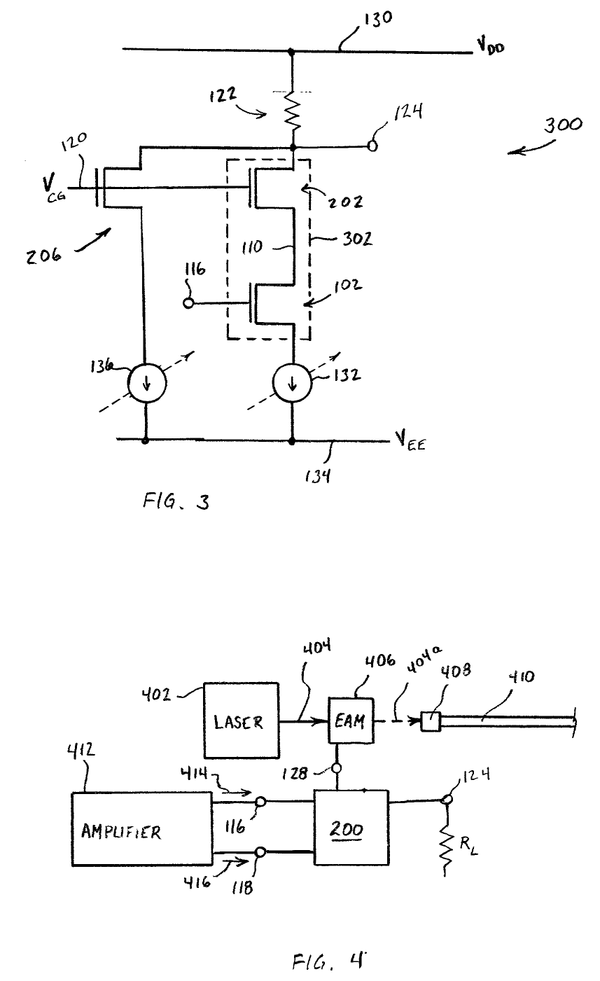

Embodiments are not confined to differential amplifier topologies. FIG. 3 illustrates an embodiment using a single cascode stage that functions in a manner similar to one side of circuit 200 (FIG. 2). In one case circuit 300 is formed on a single integrated circuit die. As illustrated in FIG. 3, only transistors 102,202,206, resistor 122, and current sources 132,136 are included in circuit 300. As described above, current source 136 causes a voltage at output terminal 124 that is a constant DC offset voltage (e.g., in the range from 0 to −1 volt) from the “top rail” supply voltage V_{DD} at node 130. The modulating input signal at input terminal 116 controls the additional output terminal 124 voltage drop caused by current source 132.

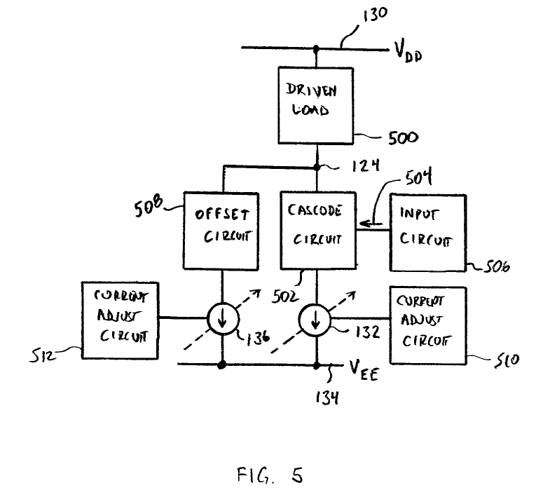

FIG. 4 is a diagrammatic view of an electro-absorptive modulator driver embodiment. Conventional laser 402 directs a continuous laser beam 404 through conventional electro-absorptive modulator 406 to conventional optical coupler 408 connected to the end of conventional optical fiber 410. Conventional electronic amplifier 412 provides digital (e.g., binary values representing logic “high” or “on” or “one” and logic “low” or “off” or “zero” ) radio frequency signals 414,416 to input terminals 116,118, respectively, of circuit 200. In one case, signals 414,416 are approximately 11 gigabit per second (Gbps) (approximately 5.5 GHz) complementary signals carrying digitized information for up to approximately 128,000 multiplexed telephone connections in accordance with the SONET OC-192 or Synchronous Digital Hierarchy (SDH) STM-64 optical communication specifications. Modulator 406 is coupled to output terminal 128 of circuit 200. Signals 414,416 control light valve operation of modulator 406, thereby producing modulated laser beam 404a which is transmitted by optical fiber 410. Since EAM 406 is an electronic load on output terminal 128, load resistor R_{L} (e.g., 50 Ohm, matching load 406) is coupled to output terminal 124 to balance the loads.

The arrangement shown in FIG. 4 is illustrative, and in other cases a conventional monolithic electroabsorption modulator laser (EML) is substituted for the discrete laser 402 and EAM 406, or a Mach-Zehnder modulator, a direct modulated laser, or a high voltage amplifier is substituted for EAM 406. In embodiments driving other loads, or using other circuit topologies such as circuit 300, the input signals to terminal 116 or terminals 116,118 may be analog or multilevel digital signals.

Embodiments are not confined for use with electro-optical drivers, and skilled artisans will appreciate that embodiments may be applied in various other circuits and systems. FIG. 5 illustrates that embodiments are used to drive any driven load 500 that requires a mixed driving voltage or current signal. The cascode circuit 502 (e.g., cascode circuit 302 (FIG. 3)) is coupled to receive a modulating input voltage or current signal 504 (e.g., discrete binary or multilevel, or analog) from an input circuit 506. Offset circuit 508 (e.g., transistor 206 (FIG. 3) provides the required offset voltage or threshold current for load 500. The current provided by cascode circuit 502 is sourced from conventional current source 132, which in some cases is fixed and in other cases, as illustrated in FIG. 5, is conventionally adjustable by a conventional adjusting circuit 510 (e.g., circuit providing variable gate voltage (e.g., discrete binary or multilevel, or analog) to an FET acting as source 132). Similarly, current provided by offset circuit 508 is sourced from conventional current source 136, which in some cases is fixed and in other cases, as illustrated in FIG. 5, is conventionally adjustable by a conventional adjusting circuit 512. In some cases one or both of circuits 510 or 512 are varied to provide the required varying voltage or current signal to load 500. Thus, as discussed above, load 500 is an optical modulator or a directly modulated laser. Or, in another case, circuits 504,508 provide a bias shift between conventional multilevel logic stages where, for example, the higher voltage output of a driving stage 506 (e.g., output Q on a D flip-flop) drives a lower voltage input on a driven stage 500 (e.g., clock input CLK on a D flip-flop). Skilled artisans will also appreciate that other cascode topologies exist and that gain devices may be combined in various circuit topologies. For instance, one or more vacuum tubes may provide a current path for a high steady state DC offset voltage at the output terminal, while a solid state cascode provides the current path for the modulating signal at the output terminal. The invention is therefore limited only by the following claims.

We claim:

1. A cascode amplifier comprising:
a first transistor comprising a control terminal and a first and a second current handling terminal, wherein the first current handling terminal of the first transistor is coupled to a first node;
a second transistor comprising a control terminal and a first and a second current handling terminal, wherein the first current handling terminal of the second transistor is coupled to the second current handling terminal of the first transistor, and wherein the second current handling terminal of the second transistor is coupled to a second node;
a third transistor comprising a control terminal and a first and a second current handling terminal, wherein the first current handling terminal of the third transistor is coupled to the first node;
a fourth transistor comprising a control terminal and a first and a second current handling terminal, wherein the first current handling terminal of the fourth transistor is coupled to the second current handling terminal of the third transistor, and wherein the second current handling terminal of the fourth transistor is coupled to a third node;
a fifth transistor comprising a control terminal and a first and a second current handling terminal, wherein the second current handling terminal of the fifth transistor is coupled to the second node;
a sixth transistor comprising a control terminal and a first and a second current handling terminal, wherein a the second current handling terminal of the sixth transistor is coupled to the third node;
a first current source coupled between the first node and a fourth node receiving a first supply voltage;
a second current source coupled between the first current handling terminal of the fifth transistor and the fourth node;
a third current source coupled between the first current handling terminal of the sixth transistor and the fourth node;
a first load resistance coupled between the second node and a fifth node receiving a second supply voltage level; and
a second load resistance coupled between the third node and the fifth node.

2. The amplifier of claim 1, wherein the control terminals of the second and fourth transistors are coupled together.

3. The amplifier of claim 1, wherein the control terminals of the fifth and sixth transistors are coupled together.

4. The amplifier of claim 1, wherein the control terminals of the second, fourth, fifth, and sixth transistors are coupled together.

5. The amplifier of claim 1, wherein the first current source is variable.

6. The amplifier of claim 1, wherein at least one of the second and third current sources is variable.

7. The amplifier of claim 1, wherein the first, second, third, fourth, fifth, and sixth transistors and the first, second, and third current sources are formed on a single integrated circuit.

8. The amplifier of claim 1, wherein the first, second, third, fourth, fifth, and sixth transistors comprise gallium arsenide.

9. The amplifier of claim 1, wherein the first, second, third, fourth, fifth, and sixth transistors comprise indium phosphide.

10. The amplifier of claim 1, wherein the first, second, third, fourth, fifth, and sixth transistors comprise silicon carbide.

11. The amplifier of claim 1, wherein the first, second, third, fourth, fifth, and sixth transistors comprise silicon-germanium.

12. The amplifier of claim 1, wherein at least one of the first, second, third, fourth, fifth, and sixth transistors is an N-type transistor, and at least one of the first, second, third, fourth, fifth, and sixth transistors is a P-type transistor.

13. The amplifier of claim 1 further comprising an electro-optical modulator coupled at the output terminal.

14. The amplifier of claim 13, wherein the modulator is an electro-absorption modulator.

15. The amplifier of claim 13, wherein the modulator is a Mach-Zehnder modulator.

16. The amplifier of claim 1 further comprising a direct modulated laser coupled at the output terminal.

17. A cascode amplifier comprising:
a first transistor comprising a control terminal and a first and a second current handling terminal;
a second transistor comprising a control terminal and a first and a second current handling terminal, wherein the first current handling terminal of the second transistor is coupled to the second current handling terminal of the first transistor;
a third transistor comprising a control terminal and a first and a second current handling terminal, wherein the second current handling terminal of the third transistor is coupled to the second current handling terminal of the second transistor;
a first current source coupled between the first current handling terminal of the first transistor and a first node receiving a supply voltage level; and
a second current source coupled between the first current handling terminal of the third transistor and the first node.

18. The amplifier of claim 17, wherein the control terminals of the second and third transistors are coupled together.

19. The amplifier of claim 17, wherein the first current source is variable.

20. The amplifier of claim 17, wherein the second current source is variable.

21. The amplifier of claim 17 further comprising a load resistance coupled between the second current handling terminal of the second transistor and a node receiving a second supply voltage.

22. The amplifier of claim 17, wherein the first, second, and third transistors, and the first and second current sources, are formed on a single integrated circuit.

23. The amplifier of claim 17, wherein the first, second, and third transistors comprise gallium arsenide.

24. The amplifier of claim 17, wherein the first, second, and third transistors comprise indium phosphide.

25. The amplifier of claim 17, wherein the first, second, and third transistors comprise silicon carbide.

26. The amplifier of claim 17, wherein the first, second, and third transistors comprise silicon-germanium.

27. The amplifier of claim 17, wherein at least one of the first, second, and third transistors is an N-type transistor, and at least one of the first, second, and third transistors is a P-type transistor.

28. The amplifier of claim 17, wherein the first, second, and third transistors comprise metal oxide semiconductor field effect transistors.

29. The amplifier of claim 17 further comprising an electro-optical modulator coupled at the output terminal.

30. The amplifier of claim 29 wherein the modulator is an electro-absorption modulator.

31. The amplifier of claim 29 wherein the modulator is a Mach-Zehnder modulator.

32. The amplifier of claim 17 further comprising a direct modulated laser coupled at the output terminal.

33. An electronic circuit comprising:
a first current path comprising a first current source, the first current path providing an offset voltage level at an output terminal of the circuit, the offset voltage level being offset from a supply voltage level of the circuit; and
a second current path comprising a cascode amplifier coupled to a second current source, the second current path providing a varying voltage level at the output terminal.

34. The circuit of claim 33, wherein the first current path comprises an electronic gain device and the offset voltage is a steady state voltage.

35. The circuit of claim 34, wherein the gain device comprises gallium arsenide.

36. The circuit of claim 35, wherein the gain device comprises indium phosphide.

37. The circuit of claim 35, wherein the gain device comprises silicon carbide.

38. The circuit of claim 35, wherein the gain device comprises silicon-germanium.

39. The circuit of claim 33, wherein the first current path comprises at least one N-type semiconductor gain device and at least one P-type semiconductor gain device.

40. The circuit of claim 33, wherein the cascode amplifier comprises at least two transistors coupled in a cascode topology.

41. The circuit of claim 40, wherein at least one of the transistors comprises gallium arsenide.

42. The circuit of claim 40, wherein at least one of the transistors comprises indium phosphide.

43. The circuit of claim 40, wherein at least one of the transistors comprises silicon carbide.

44. The circuit of claim 40, wherein at least one of the transistors comprises silicon-germanium.

45. The circuit of claim 33, wherein the cascode amplifier comprises at least one N-type semiconductor gain device and at least one P-type semiconductor gain device.

46. The circuit of claim 33, wherein the first current source is variable.

47. The circuit of claim 33, wherein the second current source is variable.

48. The circuit of claim 33 further comprising an electro-optical modulator coupled at the output terminal.

49. The circuit of claim 48, wherein the modulator is an electro-absorption modulator.

50. The circuit of claim 48, wherein the modulator is a Mach-Zehnder modulator.

51. The circuit of claim 33 further comprising a direct modulated laser coupled at the output terminal.

52. A method of providing a mixed output voltage signal at an output terminal of an electronic circuit, wherein the output signal comprises an offset voltage level and a varying voltage level, the offset voltage level being offset from a supply voltage level of the circuit, comprising the acts of:
passing a first current through a first current path, wherein the first current path comprises a load resistance and a first current source, and wherein the first current passing through the load resistance causes a first voltage drop across the load resistance that provides the offset voltage level; and
passing a varying current through a second current path, wherein the second current path comprises the load resistance, a cascode amplifier, and a second current source, and wherein the varying current passing through the load resistance causes a varying voltage drop across the load resistance that provides the varying voltage level.

53. The method of claim 52, wherein the method of providing the mixed output voltage signal further comprises driving an optical modulator coupled to the output terminal.

54. The method of claim 52, wherein passing the first current through the first current path comprises adjusting a current provided by the first current source to provide the offset voltage level required by a load being driven at the output terminal.

55. The method of claim 52, wherein passing the varying current through the second current path comprises receiving a varying electronic input signal at an input terminal of the cascode amplifier.

56. The method of claim 52, wherein the cascode amplifier comprises at least one transistor comprising gallium arsenide.

57. The method of claim 52, wherein the varying voltage level varies at least one volt.

58. The method of claim 52, wherein the varying voltage level varies between the offset voltage level and a predetermined modulating voltage level, and wherein the varying voltage level does not overshoot the modulating voltage level by more than approximately seven percent of the modulating voltage level as the varying voltage level switches from the offset voltage level to the modulating voltage level.
